(19) United States
(12) Patent Application Publication
(10) Pub. No.: US 2017/0294394 A1
(43) Pub. Date: Oct. 12, 2017

(54) SEMICONDUCTOR DEVICE HAVING A MOLECULAR BONDING LAYER FOR BONDING ELEMENTS

(71) Applicant: KABUSHIKI KAISHA TOSHIBA, Tokyo (JP)

(72) Inventors: Daigo SUZUKI, Kawasaki Kanagawa (JP); Akihiko HAPPOYA, Ome Tokyo (JP)

(21) Appl. No.: 15/442,213

(22) Filed: Feb. 24, 2017

Related U.S. Application Data
(60) Provisional application No. 62/319,697, filed on Apr. 7, 2016.
(60) Provisional application No. 62/382,045, filed on Aug. 31, 2016.

(51) Int. Cl. H01L 23/00; B32B 7/12; C07F 7/18

(52) U.S. Cl. CPC H01L 24/29; H01L 24/09; H01L 24/16; H01L 24/83; C07F 7/1812; B32B 7/12; H01L 2924/13064; H01L 2924/13091; H01L 2924/01028; H01L 2924/01029; H01L 2924/01079; B32B 2250/02; B32B 2307/202; B32B 2457/14

(57) ABSTRACT

A semiconductor device includes a substrate including, on a surface thereof, a first conductive pad and a first insulating layer formed around the first conductive pad, a semiconductor chip including, on a surface thereof, a second conductive pad and a second insulating layer around the second conductive pad, an intermediate layer formed between the substrate and the semiconductor chip, and including a conductive portion between the first and second conductive pads, and an insulating portion between the first and second insulating layers, and a molecular bonding layer formed between the substrate and the intermediate layer, and including at least one of a first molecular portion covalently bonded to a material of the first conductive pad and a material of the conductive portion, and a second molecular portion covalently bonded to a material of the first insulating layer and a material of the insulating portion.

### CROSS-REFERENCE TO RELATED APPLICATIONS

This application is based upon and claims the benefit of priority from U.S. Provisional Patent Application No. 62/319,697, filed on Apr. 7, 2016, and U.S. Provisional Patent Application No. 62/382,045, filed on Aug. 31, 2016, the entire contents of all of which are incorporated herein by reference.

### FIELD

Embodiments described herein relate generally to a semiconductor device and a method of manufacturing the semiconductor device.

### BACKGROUND

A semiconductor device including a base board, a semiconductor chip, and an intermediate layer between the base board and the semiconductor chip is known.

### BRIEF DESCRIPTION OF THE DRAWINGS

FIG. 1 is a cross-sectional view of a semiconductor device according to a first embodiment.

FIG. 2 is a schematic cross-sectional view of the semiconductor device according to the first embodiment.

FIG. 3 schematically illustrates of a composition of a molecular bonding layer according to the first embodiment.

FIG. 4 is a cross-sectional view of the molecular bonding layer along a line F4-F4 in FIG. 1.

FIG. 5 is a cross-sectional view of a structure in process to show a flow of a method of manufacturing the semiconductor device according to the first embodiment.

FIG. 6 is a cross-sectional view of a semiconductor device according to a second embodiment.

FIG. 7 is a cross-sectional view of a molecular bonding layer along a line F7-F7 in FIG. 6.

FIG. 8 is a cross-sectional view of a structure in process to show a flow of a method of manufacturing the semiconductor device according to the second embodiment.

FIG. 9 is a plan view of a mask according to the second embodiment.

FIG. 10 is a cross-sectional view of a semiconductor device according to a third embodiment.

FIG. 11 is an enlarged cross-sectional view of a vicinity of a first conductive portion in the semiconductor package according to the third embodiment.

FIG. 12 is a plan view of a mask according to the third embodiment.

FIG. 13 is a cross-sectional view of a semiconductor device according to a fourth embodiment.

FIG. 14 is a plan view of a mask according to the fourth embodiment.

FIG. 15 is a cross-sectional view of a part of a semiconductor device according to a modified example of the fourth embodiment.

FIG. 16 is a cross-sectional view of a semiconductor device according to a fifth embodiment.

FIG. 17 is an enlarged cross-sectional view of a vicinity of a heat conductive sheet in the semiconductor package according to the fifth embodiment.

FIG. 18 is a perspective view of an electronic device including the semiconductor package according to embodiments.

### DETAILED DESCRIPTION

A semiconductor device according to an embodiment includes a substrate including, on a surface thereof, a first conductive pad and a first insulating layer formed around the first conductive pad, a semiconductor chip including, on a surface thereof, a second conductive pad and a second insulating layer around the second conductive pad, an intermediate layer between the substrate and the semiconductor chip, and including a conductive portion between the first and second conductive pads, and an insulating portion between the first and second insulating layers, and a molecular bonding layer between the substrate and the intermediate layer, and including at least one of a first molecular portion covalently bonded to a material of the first conductive pad and a material of the conductive portion, and a second molecular portion covalently bonded to a material of the first insulating layer and a material of the insulating portion.

Hereinafter, a semiconductor device and a method of producing a semiconductor device according to embodiments will be described with reference to the drawings. In the following description, components having the same or similar functions are denoted by the same reference numerals and redundant descriptions thereof will be omitted. It is noted that the drawings are schematic and the numbers, thicknesses, widths, proportions, and the like of components may be different from actual components.

### First Embodiment

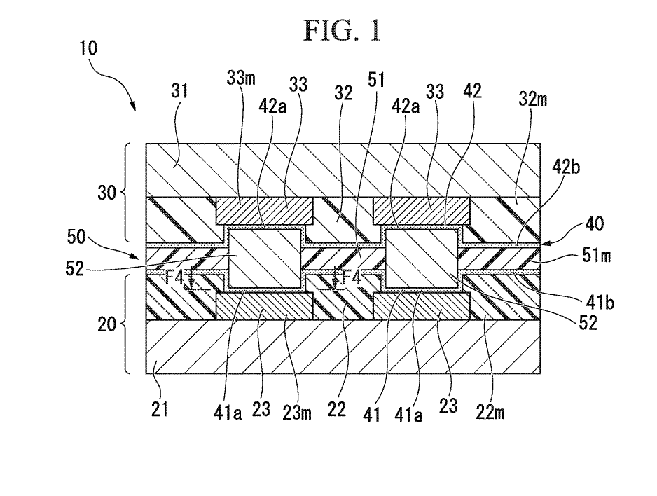

A first embodiment will be described with reference to FIG. 1 to FIG. 5.

FIG. 1 is a cross-sectional view of a semiconductor package (device) 10 according to the first embodiment.

The semiconductor package 10 is a semiconductor component that is used as, for example, a vehicle component and a power semiconductor. However, the semiconductor package 10 is not limited to the vehicle component and the power semiconductor, and may be a semiconductor component that is used for other purposes.

As shown in FIG. 1, the semiconductor package 10 according to the present embodiment includes a base board 20, a semiconductor chip 30, at least one molecular bonding layer 40, and an intermediate layer 50.

The base board 20 is an example of a “board.” The base board 20 includes a base board main body 21, a first insulation portion 22, and a plurality of first conductive portions 23. The base board main body 21 is formed of, for example, an organic material or an inorganic material. The base board main body 21 may be made of a material having high thermal conductivity. By using the material having high thermal conductivity, heat dissipation properties when the semiconductor package 10 operates are enhanced. For example, the base board main body 21 is formed of an insulator such as an organic compound, a semiconductor, or a conductor such as a partially insulated metal. For example, the base board main body 21 has a wiring pattern. At least one of an electrical signal from the semiconductor chip 30 and an electrical signal to the semiconductor chip 30 is transmitted through the wiring pattern of the base board main body 21. The base board main body 21 may be a multilayer board. For example, a part of the base board main body 21 may be formed of metal. If a part of the base board main body 21 is formed of metal, it is possible to further increase thermal conductivity of the semiconductor package 10. Exemplary metal of the part of the base board main body 21 includes Cu, Mo, Ag, W, or alloys thereof. For example, as the metal, Cu or an alloy of Cu and Mo is preferably used. If the metal is used as a material of a part of the base board 20, thermal conductivity further increases.

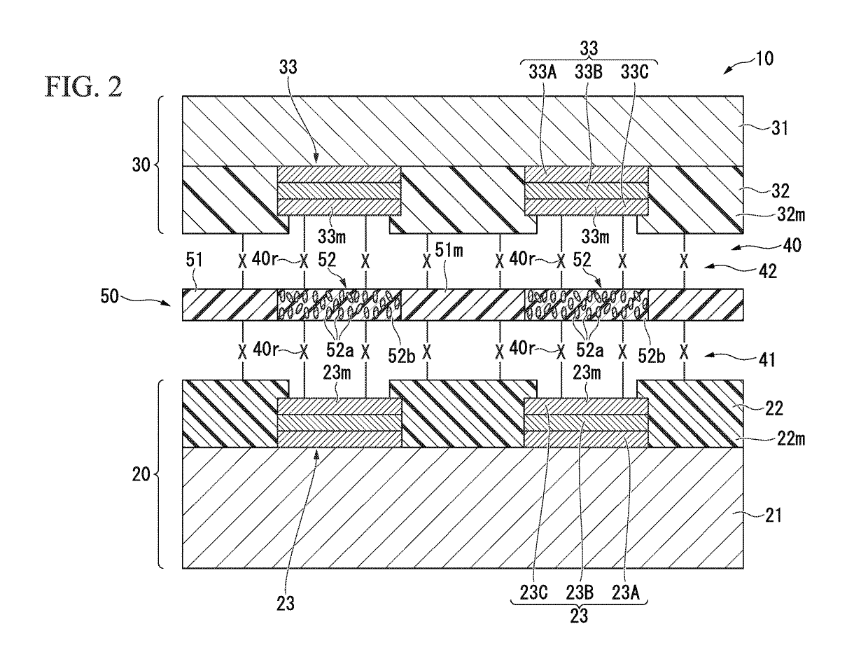

The first conductive portion 23 is, for example, a conductive pad (i.e., a connection portion, an electrical connection portion, and a terminal) formed on a surface of the base board main body 21. The first conductive portion 23 forms a part of a circuit that is formed on the base board main body 21. The first conductive portion 23 is made of a first conductive material 23m. For example, the first conductive portion 23 is a metal plating portion that is formed on a part of a surface of the base board main body 21 using the first conductive material 23m. As the first conductive material 23m, for example, Au, Ni, Cu, Pt, Sn, or Pd is used. In the present embodiment, the first conductive portion 23 has a structure in which a Ni plating (i.e., a second plating layer) 23B and an Au plating (i.e., a third plating layer) 23C are sequentially laminated on a Cu plating (i.e., a first plating layer) 23A (refer to FIG. 2). For example, the Cu plating 23A serves as a base of the first conductive portion 23. When the base board main body 21 is viewed in a plan view, the first conductive portion 23 is formed in, for example, a circular shape. In the present embodiment, the first conductive material 23m is, for example, Au that is used to form a surface layer of the first conductive portion 23.

The first insulation portion 22 is, for example, a resist layer (e.g., a solder resist) formed on a surface of the base board main body 21, and is formed on the base board main body 21 using a first insulating material 22m. For example, the first insulation portion 22 is formed by the first insulating material 22m being formed in a part in which the first conductive portions 23 are not formed within the surface of the base board main body 21. The first insulation portion 22 electrically insulates a portion in which the first conductive portions 23 are not formed on the base board 20. That is, the first insulation portion 22 can prevent a short circuit between, for example, a plurality of first conductive portions 23. As the first insulating material 22m, for example, an acrylic resin, an oxetane resin, or an epoxy resin, is used. In the present embodiment, the first insulation portion 22 is formed of an epoxy resin on the base board main body 21 after the first conductive portion 23 is formed.

The semiconductor chip (e.g., a bare chip) 30 includes a semiconductor chip main body 31, a second insulation portion 32, and a plurality of second conductive portions 33. The semiconductor chip main body 31 is, for example, a heterojunction field effect transistor (HFET) made of a GaN or SiC material or a lateral double diffuse MOS transistor (LDMOS) made of a Si material. In addition, as other examples of the semiconductor chip main body 31, an optical semiconductor element, a piezoelectric element, a memory element, a microcomputer element, a sensor element, and a wireless communication element are exemplified. The term “semiconductor chip (or semiconductor chip main body)” referred to herein may indicate any component including an electric circuit and is not limited to a specific semiconductor chip.

The second conductive portion 33 is, for example, a conductive pad (i.e., a connection portion, an electrical connection portion, or a terminal) formed on a surface of the semiconductor chip main body 31. The second conductive portion 33 forms a part of a circuit that is formed on the semiconductor chip main body 31. The second conductive portion 33 is made of a second conductive material 33m. For example, the second conductive portion 33 is a metal plating portion that is formed on a part of a surface of the semiconductor chip main body 31 using the second conductive material 33m. As the second conductive material 33m, for example, Au, Ni, or Cu is used. In the present embodiment, the second conductive portion 33 has a structure in which a Ni plating (i.e., a second plating layer) 33B, and an Au plating (i.e., a third plating layer) 33C are sequentially laminated on a Cu plating (i.e., a first plating layer) 33A (refer to FIG. 2). For example, the Cu plating 33A serves as a base of the second conductive portion 33. When the semiconductor chip main body 31 is viewed in a plan view, the second conductive portion 33 is formed in, for example, a circular shape. In the present embodiment, the second conductive material 33m is, for example, Au that is used to form a surface layer of the second conductive portion 33. It is noted that the second conductive material 33m may be the same as or different from the first conductive material 23m.

The second insulation portion 32 is, for example, a resist layer (e.g., a solder resist) formed on a surface of the semiconductor chip main body 31 and is formed on the semiconductor chip main body 31 using a second insulating material 32m. For example, the second insulation portion 32 is formed by the second insulating material 32m being formed in a part in which the second conductive portions 33 are not formed within the surface of the semiconductor chip main body 31. The second insulation portion 32 electrically insulates a portion in which the second conductive portions 33 are not formed on the semiconductor chip main body 31, and can prevent a short circuit between, for example, a plurality of second conductive portions 33. As the second insulating material 32m, for example, a polyimide resin can be used. In the present embodiment, the second insulation portion 32 is formed of a polyimide resin on the semiconductor chip main body 31 after the second conductive portion 33 is formed by metal plating. It is noted that the second insulating material 32m may be the same as or different from the first insulating material 22m.

The intermediate layer 50 is formed between the base board 20 and the semiconductor chip 30. For example, the intermediate layer 50 is a connection member that electrically and physically connects (e.g., joins) the base board 20 and the semiconductor chip 30. The intermediate layer 50 includes a third insulation portion 51 and a plurality of third conductive portions 52.

The third conductive portion 52 is formed at positions corresponding to the first conductive portion 23 of the base board 20 and the second conductive portion 33 of the semiconductor chip 30, within the intermediate layer 50. The third conductive portion 52 is formed between the first conductive portion 23 of the base board 20 and the second conductive portion 33 of the semiconductor chip 30 and between the first conductive portion 23 and the second conductive portion 33. The third conductive portion 52 electrically connects the first conductive portion 23 and the second conductive portion 33.

The third conductive portion 52 includes a plurality of conductive particles 52a and a resin 52b (i.e., a resin portion e.g., a synthetic resin) (refer to FIG. 2). The third conductive portion 52 has conductivity by the plurality of conductive particles 52a included in the third conductive portion 52 being in contact with each other and being electrically connected with each other. In other words, the plurality of conductive particles 52a electrically connects the first conductive portion 23 to the second conductive portion 33. The conductive particles 52a are particles that include a conductive material. The conductive particles 52a have, for example, ellipsoidal shapes, rectangular parallelepiped shapes, or scaly shapes, but the shapes are not limited. The conductive material included in the conductive particles 52a can be appropriately selected. For example, a metal having high conductivity is used as the conductive particles 52a. As the conductive particles 52a, for example, Ag, Cu, Ni or Ag is used. The conductive particles 52a may be particles made of a conductive material in which the above plurality of types of metal is mixed. For example, the conductive particles 52a may be particles having layers of a plurality of metal materials in which each particle includes one type among the above plurality of metal materials, is covered with another metal material, and further covered with another metal material. Diameters of the conductive particles 52a are, for example, 2 μm or more, preferably 5 μm or more and 50 μm or less, and more preferably 30 μm or less. For example, the conductive particles 52a may have diameters of 2 μm to 30 μm or 5 μm to 50 μm depending on materials. For example, a content of the conductive particles 52a with respect to a total mass of the third conductive portion 52 may be 50 to 95 mass %. For example, conductivity of the third conductive portion 52 in the above range is favorable. In the present embodiment, a third conductive portion 53 is formed of silver paste in which Ag particles are used as the conductive particles 52a.

The resin 52b of the third conductive portion 52 can be appropriately selected, but, for example, a resin that contracts during curing may be used. As the resin 52b of the third conductive portion 52, for example, an acrylic resin, an epoxy resin, a silicone resin, a phenol resin, an imide resin, an amide resin or an elastomer is used. In the present embodiment, as the resin 52b of the third conductive portion 52, the epoxy resin is used. In the present embodiment, the third conductive portion 52 is a cured product obtained by curing silver paste in which Ag particles serving as the conductive particles 52a are dispersed in the resin 52b. When the intermediate layer 50 is viewed in a plan view, the third conductive portion 52 is formed in, for example, a circular shape.

The third insulation portion 51 is formed at positions corresponding to the first insulation portion 22 of the base board 20 and the second insulation portion 32 of the semiconductor chip 30, within the intermediate layer 50. The third insulation portion 51 is formed between the first insulation portion 22 of the base board 20 and the second insulation portion 32 of the semiconductor chip 30, and between the first insulation portion 22 and the second insulation portion 32. The third insulation portion 51 is joined to the first insulation portion 22 and the second insulation portion 32 according to, for example, an anchor effect.

The third insulation portion 51 is made of a third insulating material 51m. For example, the third insulation portion 51 is formed in a portion in which the third conductive portion 52 is not formed within the intermediate layer 50. The third insulation portion 51 electrically insulates the plurality of third conductive portions 52. The third insulation portion 51 can prevent a short circuit between a plurality of electrical connection paths formed by the plurality of third conductive portions 52. For example, as the third insulating material 51m, various types of non-conductive paste (NCP), non-conductive films (NCFs), and the like are used. In the present embodiment, the third insulation portion 51 is made of an epoxy resin. The third insulating material 51m may be the same as or different from the first insulating material 22m and the second insulating material 32m.

As described above, in the present embodiment, the first conductive portion 23 of the base board 20 and the second conductive portion 33 of the semiconductor chip 30 are electrically connected through the third conductive portion 52. That is, the first conductive portion 23 and the second conductive portion 33 are electrically connected through the third conductive portion 52 by disposing and stacking the intermediate layer 50 between the base board 20 and the semiconductor chip 30.

Similarly, the first insulation portion 22 and the second insulation portion 32 are joined to the third insulation portion 51. That is, the first insulation portion 22 and the second insulation portion 32 are joined through the third insulation portion 51 by disposing and stacking the intermediate layer 50 between the base board 20 and the semiconductor chip 30.

Materials of the third conductive portion 52 and the third insulation portion 51 are applied in a flexible state, and are cured between the base board 20 and the semiconductor chip 30, for example.

Next, the molecular bonding layer 40 will be described.

FIG. 2 is a schematic cross-sectional view of the semiconductor package 10.

As shown in FIG. 1 and FIG. 2, the semiconductor package 10 of the present embodiment includes at least one molecular bonding layer 40. The at least one molecular bonding layer 40 is formed between the third conductive portion 52 and at least one of the first conductive portion 23 and the second conductive portion 33. In addition, in a different point of view, the molecular bonding layer 40 is formed between the third insulation portion 51 and at least one of the first insulation portion 22 and the second insulation portion 32. Although the molecular bonding layer 40 is actually very thin, it is drawn with a certain thickness in FIGS. 1 and 2 for convenience of description.

As shown in FIG. 1, in the present embodiment, the at least one molecular bonding layer 40 includes a first molecular bonding layer 41 and a second molecular bonding layer 42. The first molecular bonding layer 41 is formed on a surface of the first conductive portion 23 and a surface of the first insulation portion 22. The second molecular bonding layer 42 is formed on a surface of the second conductive portion 33 and a surface of the second insulation portion 32.

In other words, the first molecular bonding layer 41 is formed between the base board 20 and the intermediate layer 50. The first molecular bonding layer 41 includes a plurality of first portions 41a that are formed between the plurality of first conductive portions 23 and the plurality of third conductive portions 52 and a second portion 41b that is formed between the first insulation portion 22 and the third insulation portion 51. The first portion 41a of the first molecular bonding layer 41 is chemically bonded to both the first conductive portion 23 and the third conductive portion 52 and joins the first conductive portion 23 and the third conductive portion 52 with the chemical bonding. The second portion 41b of the first molecular bonding layer 41 is chemically bonded to both the first insulation portion 22 and the third insulation portion 51 and joins the first insulation portion 22 and the third insulation portion 51 with the chemical bonding. The first portion 41a and the second portion 41b are, for example, integrally formed with each other (i.e., formed in a series with each other).

On the other hand, the second molecular bonding layer 42 is formed between the semiconductor chip 30 and the intermediate layer 50. The second molecular bonding layer 42 includes a plurality of first portions 42a that are formed between the plurality of second conductive portions 33 and the plurality of third conductive portions 52 and a second portion 42b that is formed between the second insulation portion 32 and the third insulation portion 51. The first portion 42a of the second molecular bonding layer 42 is chemically bonded to both the second conductive portion 33 and the third conductive portion 52 and joins the second conductive portion 33 and the third conductive portion 52 with the chemical bonding. The second portion 42b of the second molecular bonding layer 42 is chemically bonded to both the second insulation portion 32 and the third insulation portion 51 and joins the second insulation portion 32 and the third insulation portion 51 with the chemical bonding. The first portion 42a and the second portion 42b are, for example, integrally formed with each other (i.e., formed in a series with each other).

Hereinafter, the first molecular bonding layer 41 and the second molecular bonding layer 42 will be described in detail.

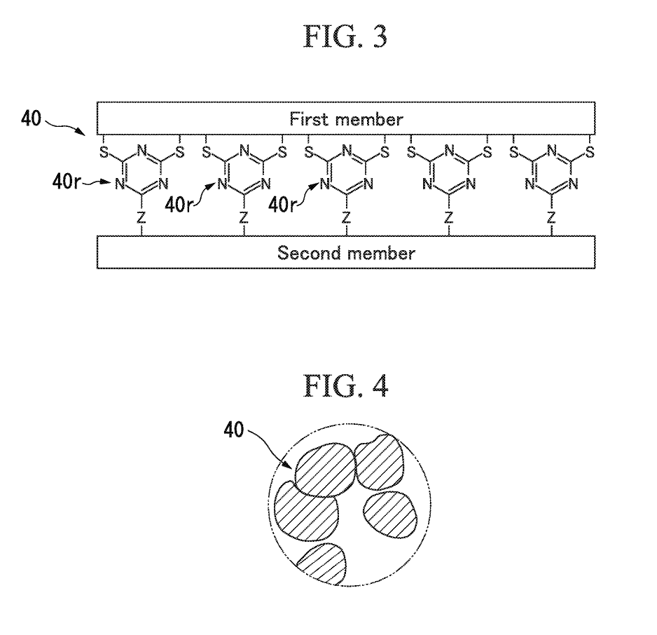

The molecular bonding layer 40 of the present embodiment joins the intermediate layer 50 and the base board 20 and also joins the intermediate layer 50 and the semiconductor chip 30. The molecular bonding layer 40 includes molecular bonding systems 40r (refer to FIG. 3) formed by a molecular bonding agent. The molecular bonding agent is a compound capable of forming, for example, a chemical bond (e.g., a covalent bond) with a resin and a metal. The term “covalent bond” herein broadly refers to a bond having a covalent bonding property and includes a coordinate bond, a semi-covalent bond, and the like. In addition, the term “molecular bonding system” herein refers to a substance that remains in a joint part after a molecular bonding agent is chemically bonded (i.e., chemically reacted).

As the molecular bonding agent, for example, a compound such as a triazine derivative is exemplified. As the triazine derivative, a compound expressed by the following General Formula (C1) is exemplified.

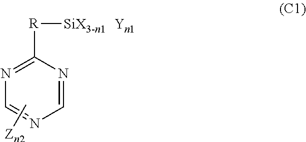

(where, R represents a hydrocarbon group or a hydrocarbon group which may include a hetero atom or a functional group therebetween; X represents a hydrogen atom or a hydrocarbon group; Y represents an alkoxy group; Z represents a thiol group, an amino group or an azido group, which may be a salt, or a hydrocarbon group which may include a hetero atom or a functional group therebetween; n1 represents an integer of 1 to 3; and n2 represents an integer of 1 to 2.)

In General Formula (C1), R is preferably a hydrocarbon group having 1 to 7 carbon atoms or a group having a main chain in which a nitrogen atom is included. X represents a hydrocarbon group having 1 to 3 carbon atoms. Y represents an alkoxy group having 1 to 3 carbon atoms. n1 is preferably 3. n2 is preferably 2. Z preferably represents a thiol group, an amino group or an azido group, which may be a salt, or an alkyl group. As a cation element that forms a salt, an alkali metal is preferable. Among alkali metals, Li, Na, K or Cs is more preferable. When n2 is 2, at least one Z is preferably a thiol group, an amino group, or an azido group, which is a salt.

At least a part of the first portion 41a of the first molecular bonding layer 41 (i.e., at least a part of a molecular bonding agent that forms the first molecular bonding layer 41) is chemically bonded (e.g., covalently bonded) to the first conductive material 23m of the first conductive portion 23. Similarly, at least a part of the first portion 41a of the first molecular bonding layer 41 (i.e., at least a part of a molecular bonding agent that forms the first molecular bonding layer 41) is chemically bonded (e.g., covalently bonded) to the resin 52b of the third conductive portion 52. In addition, at least a part of the first portion 41a of the first molecular bonding layer 41 (i.e., at least a part of a molecular bonding agent that forms the first molecular bonding layer 41) is chemically bonded (e.g., covalently bonded) to the conductive particles 52a of the third conductive portion 52. Therefore, the first portion 41a of the first molecular bonding layer 41 joins the first conductive portion 23 and the third conductive portion 52.

FIG. 3 schematically illustrates a composition of the molecular bonding layer 40. As shown in FIG. 3, the first molecular bonding layer 41 includes, for example, a plurality of molecular bonding systems 40r. The molecular bonding system 40r includes a molecular bonding agent residue that is formed when the above-described molecular bonding agent is chemically reacted with bonding targets (a first member and a second member). For example, the molecular bonding system 40r includes a molecular bonding agent residue that is formed when the above-described molecular bonding agent is chemically reacted with the first conductive portion 23 and the third conductive portion 52. The molecular bonding agent residue is, for example, a triazine dithiol residue, as shown in FIG. 3. The molecular bonding system 40r may include “S” or “Z” in FIG. 3. An example of “Z” in FIG. 3 is an amino hydrocarbylsiloxy group.

For example, at least one molecular bonding system 40r included in the first molecular bonding layer 41 is chemically bonded (e.g., covalently bonded) to both the first conductive material 23m of the first conductive portion 23 and the resin 52b of the third conductive portion 52. In addition, at least one other molecular bonding system 40r included in the first molecular bonding layer 41 is chemically bonded (e.g., covalently bonded) to both the first conductive material 23m of the first conductive portion 23 and the conductive particles 52a of the third conductive portion 52.

As shown in FIG. 1, at least a part of the second portion 41b of the first molecular bonding layer 41 (i.e., at least a part of a molecular bonding agent that forms the first molecular bonding layer 41) is chemically bonded (e.g., covalently bonded) to the first insulating material 22m of the first insulation portion 22. Similarly, at least a part of the second portion 41b of the first molecular bonding layer 41 (i.e., at least a part of a molecular bonding agent that forms the first molecular bonding layer 41) is chemically bonded (e.g., covalently bonded) to the third insulating material 51m of the third insulation portion 51. As a result, the second portion 41b of the first molecular bonding layer 41 joins the first insulation portion 22 and the third insulation portion 51.

For example, at least one molecular bonding system 40r included in the first molecular bonding layer 41 is chemically bonded (e.g., covalently bonded) to both the first insulating material 22m of the first insulation portion 22 and the third insulating material 51m of the third insulation portion 51.

Similarly, at least a part of the first portion 42a of the second molecular bonding layer 42 (i.e., at least a part of a molecular bonding agent that forms the second molecular bonding layer 42) is chemically bonded (e.g., covalently bonded) to the second conductive material 33m of the second conductive portion 33. Similarly, at least a part of the first portion 42a of the second molecular bonding layer 42 (i.e., at least a part of a molecular bonding agent that forms the second molecular bonding layer 42) is chemically bonded (e.g., covalently bonded) to the resin 52b of the third conductive portion 52. In addition, at least a part of the first portion 42a of the second molecular bonding layer 42 (i.e., at least a part of a molecular bonding agent that forms the second molecular bonding layer 42) is chemically bonded (e.g., covalently bonded) to the conductive particles 52a of the third conductive portion 52. As a result, the first portion 42a of the second molecular bonding layer 42 joins the second conductive portion 33 and the third conductive portion 52.

For example, at least one molecular bonding system 40r included in the second molecular bonding layer 42 is chemically bonded (e.g., covalently bonded) to both the second conductive material 33m of the second conductive portion 33 and the resin 52b of the third conductive portion 52. In addition, at least one other molecular bonding system 40r included in the second molecular bonding layer 42 is chemically bonded (e.g., covalently bonded) to both the second conductive material 33m of the second conductive portion 33 and the conductive particles 52a of the third conductive portion 52.

At least a part of the second portion 42b of the second molecular bonding layer 42 (i.e., at least a part of a molecular bonding agent that forms the second molecular bonding layer 42) is chemically bonded (e.g., covalently bonded) to the second insulating material 32m of the second insulation portion 32. Similarly, at least a part of the second portion 42b of the second molecular bonding layer 42 (i.e., at least a part of a molecular bonding agent that forms the second molecular bonding layer 42) is chemically bonded (e.g., covalently bonded) to the third insulating material 51m of the third insulation portion 51. As a result, the second portion 42b of the second molecular bonding layer 42 joins the second insulation portion 32 and the third insulation portion 51.

For example, at least one molecular bonding system 40r included in the second molecular bonding layer 42 is chemically bonded (e.g., covalently bonded) to both the second insulating material 32m of the second insulation portion 32 and the third insulating material 51m of the third insulation portion 51.

In other words, in the first conductive portion 23 on which the first molecular bonding layer 41 is formed or the second conductive portion 33 on which the second molecular bonding layer 42 is formed, the molecular bonding agent is chemically bonded (e.g., covalently bonded) to materials included in the first conductive portion 23 and the second conductive portion 33. Therefore, the intermediate layer 50 and each of the base board 20 and the semiconductor chip 30 are firmly bonded.

An adhesion strength between the intermediate layer 50 and the base board 20 or between the intermediate layer 50 and the semiconductor chip 30 is preferably 2 MPa or more, more preferably 5 MPa or more, still more preferably 6 MPa or more, and most preferably 10 MPa or more. In addition, a breaking mode when the adhesion strength is measured is preferably a mode in which the intermediate layer 50 rather than a bonding interface is broken. The adhesion strength can be measured by, for example, a die shear test. As a specific example of a tensile test, methods defined in MIL-STD883Q IEC-60749-19, EIAJ ED-4703, and the like are exemplified.

The molecular bonding agent is covalently bonded to the first conductive material 23m or the second conductive material 33m and the resin 52b of the third conductive portion 52, and joints the first conductive portion 23 or the second conductive portion 33 and the resin 52b of the third conductive portion 52. Since the above-described molecular bonding agent can be chemically bonded (e.g., covalently bonded) to both the conductive material and the resin, the first conductive portion 23 or the second conductive portion 33 and the resin 52b of the third conductive portion 52 can be jointed with a strong adhesive force. In addition, when the molecular bonding agent is chemically bonded (e.g., covalently bonded) to the first conductive material 23m or the second conductive material 33m and the resin 52b of the third conductive portion 52, a distance between the first conductive portion 23 or the second conductive portion 33 and the third conductive portion 52 is shorter and an electrical connection between the conductive particles 52a of the third conductive portion 52 and the first conductive portion 23 or the second conductive portion 33 is more reliable.

That is, when the molecular bonding layer is not formed, if a ratio of an area occupied by the resin 52b with respect to the size of the semiconductor package 10 increases, there is a risk of the intermediate layer 50 being peeled off from the first conductive portion 23 or the second conductive portion 33 due to contraction of the resin 52b. On the other hand, in the present embodiment, since the molecular bonding layer 40 is chemically bonded (e.g., covalently bonded) to at least one of the first conductive material 23m and the second conductive material 33m, it is difficult for the third conductive portion 52 and at least one of the first conductive portion 23 and the second conductive portion 33 to peel off. Therefore, it is possible to suppress a decrease in the adhesive force and a decrease in electrical connectivity.

For example, when the first molecular bonding layer 41 formed on the surface of the first conductive portion 23 is chemically bonded (e.g., covalently bonded) to the first conductive material 23m and the resin 52b of the third conductive portion 52 and the second molecular bonding layer 42 formed on the surface of the second conductive portion 33 is chemically bonded (e.g., covalently bonded) to the second conductive material 33m and the resin 52b of the third conductive portion 52, since distances between the first conductive portion 23, the third conductive portion 52, and the second conductive portion 33 are shorter due to the molecular bonding agent, the conductive particles 52a and each of the first conductive material 23m and the second conductive material 33m are electrically connected more favorably, and an electrical connection between the base board 20 and the semiconductor chip 30 is ensured more reliably.

In the present embodiment, the conductive particles 52a of the third conductive portion 52 are chemically bonded (e.g., covalently bonded) to at least one of the first molecular bonding layer 41 and the second molecular bonding layer 42. When the conductive particles 52a and the molecular bonding layer 40 are chemically bonded (e.g., covalently bonded), stronger adhesiveness and conductivity are ensured.

In the present embodiment, one molecule (e.g., the molecular bonding system 40r) of the molecular bonding agent in the first molecular bonding layer 41 is chemically bonded (e.g., covalently bonded) to both the resin 52b of the third conductive portion 52 and the first conductive material 23m. In addition, one molecule (e.g., the molecular bonding system 40r) of the molecular bonding agent in the second molecular bonding layer 42 is chemically bonded (e.g., covalently bonded) to both the resin 52b of the third conductive portion 52 and the second conductive material 33m. When the first conductive material 23m or the second conductive material 33m and the resin 52b are joined via one molecule of the molecular bonding agent, stronger adhesiveness and conductivity are ensured. In the presents embodiment, one molecule (e.g., the molecular bonding system 40r) of the molecular bonding agent in the first molecular bonding layer 41 is chemically bonded (e.g., covalently bonded) to both the conductive particles 52a of the third conductive portion 52 and the first conductive material 23m. In addition, one molecule (e.g., the molecular bonding system 40r) of the molecular bonding agent in the second molecular bonding layer 42 is chemically bonded (e.g., covalently bonded) to both the conductive particles 52a of the third conductive portion 52 and the second conductive material 33m. In such a configuration, a stronger electrical connection between the base board 20 and the semiconductor chip 30 is ensured.

The first molecular bonding layer 41 and the second molecular bonding layer 42 each may have a thickness of 1 nm to 20 nm. A coverage ratio of the molecular bonding agent (i.e., a coverage ratio of the molecular bonding layer 40) with respect to an area of the first conductive portion 23 or the second conductive portion 33 is 20% or more and 80% or less. The above coverage ratio is preferably 30% or more and 70% or less and more preferably 40% or more and 60% or less. Also, when the coverage ratio of the molecular bonding agent is 100%, it means that the molecular bonding agent is packed theoretically closest with respect to a surface of a target to be covered. The coverage ratio of the molecular bonding agent can be obtained based on results measured by an X-ray diffraction method.

When a coverage ratio of the molecular bonding agent (i.e., a coverage ratio of the molecular bonding layer 40) with respect to the first conductive portion 23 or the second conductive portion 33 is the lower limit value or more, adhesiveness between the first conductive portion 23 or the second conductive portion 33 and the third conductive portion 52 can be further increased. In addition, when a coverage ratio of the molecular bonding agent (i.e., a coverage ratio of the molecular bonding layer 40) with respect to the first conductive portion 23 or the second conductive portion 33 is the upper limit value or less, an electrical connection between the first conductive portion 23 or the second conductive portion 33 and the third conductive portion 52 can be ensured.

FIG. 4 is a cross-sectional view of the molecular bonding layer 40 shown in FIG. 1 along a line F4-F4.

As shown in FIG. 4, for example, the molecular bonding systems 40r of the molecular bonding layer 40 may be not completely uniformly dispersed. The conductive particles 52a of the third conductive portion 52 are in contact with the first conductive portion 23 or the second conductive portion 33 at positions (i.e., regions in which the molecular bonding system 40r does not exist) between the plurality of molecular bonding systems 40r. As a result, the conductive particles 52a of the third conductive portion 52 are electrically connected to the first conductive portion 23 or the second conductive portion 33.

In the present embodiment, the first molecular bonding layer 41 extends over the first insulation portion 22 in addition to the first conductive portion 23. The second molecular bonding layer 42 extends over the second insulation portion 32 in addition to the second conductive portion 33. That is, the first molecular bonding layer 41 including the molecular bonding system 40r is formed on the surface of the first insulation portion 22. The second molecular bonding layer 42 including the molecular bonding system 40r is formed on the surface of the second insulation portion 32. At least a part of the first molecular bonding layer 41 is chemically bonded (e.g., covalently bonded) to the first insulating material 22m included in the first insulation portion 22. At least a part of the second molecular bonding layer 42 is chemically bonded (e.g., covalently bonded) to the second insulating material 32m included in the second insulation portion 32. At least a part of the first molecular bonding layer 41 or the second molecular bonding layer 42 is chemically bonded (e.g., covalently bonded) to the third insulating material 51m included in the third insulation portion 51. When the molecular bonding layer 40 is chemically bonded (e.g., covalently bonded) to the third insulating material 51m and the first insulating material 22m and/or the second insulating material 32m, adhesiveness of the first insulation portion 22 and/or the second insulation portion 32 with the third insulation portion 51 increases. When adhesiveness of the first insulation portion 22 and the second insulation portion 32 with the third insulation portion 51 increases, mutual adhesiveness of the first, second, and third conductive portions 23, 33, and 52 increases, which contributes to increased conductivity.

For example, at least a part of the first molecular bonding layer 41 and the second molecular bonding layer 42 has a monomolecular (molecular monolayer) film form. That is, at least a part of the first molecular bonding layer 41 and the second molecular bonding layer 42 is formed of a monomolecular layer. In the present embodiment, all of the first molecular bonding layer 41 and the second molecular bonding layer 42 have monomolecular film forms. In a portion that is formed in a monomolecular film form in the first molecular bonding layer 41 and the second molecular bonding layer 42, one molecule of the molecular bonding agent (i.e., the molecular bonding system 40r) is chemically bonded (e.g., covalently bonded) to both the first conductive material 23m and the resin 52b. Alternatively, one molecule of the molecular bonding agent is chemically bonded (e.g., covalently bonded) to both the second conductive material 33m and the resin 52b. As a result, it is possible to further increase adhesiveness of the first conductive portion 23 and the second conductive portion 33 with the intermediate layer 50. In addition, it is possible to ensure an electrical connection between each of the first conductive portion 23 and the second conductive portion 33 and the intermediate layer 50. Further, an increase in the thickness of the semiconductor package 10 due to the first molecular bonding layer 41 and the second molecular bonding layer 42 is minimized.

Portions occupying most areas of the first molecular bonding layer 41 and the second molecular bonding layer 42 preferably have monomolecular film forms. For example, within the surface of the first conductive portion 23 or the second conductive portion 33, a portion corresponding to 30 to 100% of an area covered by the first molecular bonding layer 41 and the second molecular bonding layer 42 more preferably has a monomolecular film form. When the area of the monomolecular film form fulfills this condition, adhesiveness and an electrical connection due to the first molecular bonding layer 41 and the second molecular bonding layer 42 are ensured more reliably.

For example, the insulation portion such as an epoxy resin is not easy to join directly with a conductor, for example, an Au plating portion. For that reason, when the first conductive portion 23 or the second conductive portion 33 has a large area conductor pattern, an adhesive force between the large area conductor pattern and the insulation portion is likely to decrease. However, according to the configuration of the present embodiment, the molecular bonding layer 40 can cause the insulation portion to adhere to the large area conductor pattern. It is noted that the term “large area conductor pattern” herein refers to, for example, a heat dissipation conductor pattern (e.g., a heat dissipation pad), a ground pattern (e.g., a ground pad) that is electrically connected to a ground of the semiconductor chip 30, or a power supply pattern (e.g., a power supply pad). The shape of the conductor pattern is not particularly limited, and may be a polygonal shape or a circular shape. When the conductor pattern has a polygonal shape, one side of the conductor pattern is greater than, for example, the thickness of the semiconductor chip 30. Similarly, when the conductor pattern has a circular shape, the diameter of the conductor pattern is greater than, for example, the thickness of the semiconductor chip 30. In addition, in another point of view, one side (or a diameter) of the conductor pattern is longer than, for example, half a length of one side of the semiconductor chip 30.

Next, a method of manufacturing the semiconductor package 10 of the present embodiment will be described.

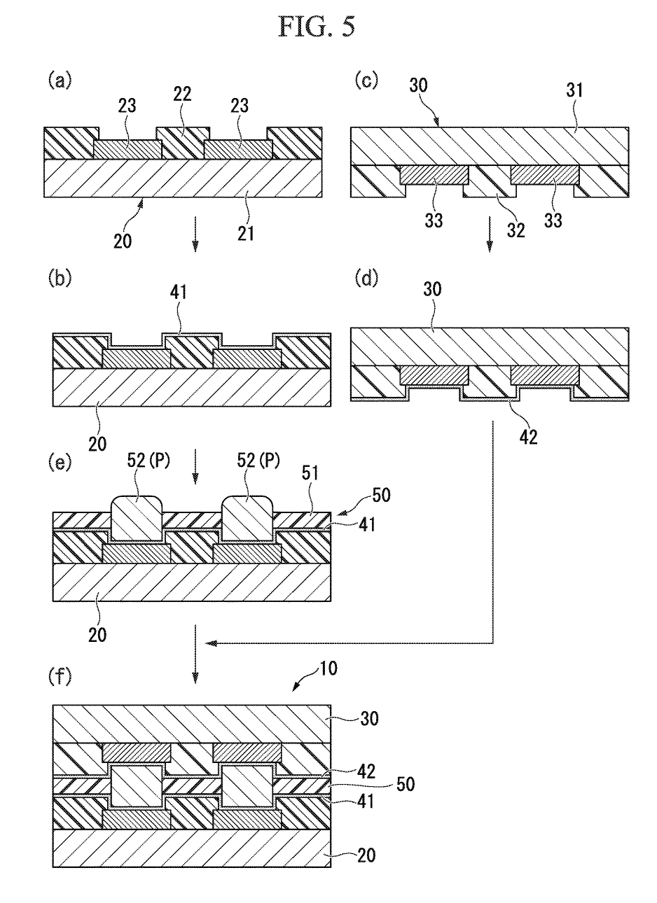

FIG. 5 is a cross-sectional view of a structure in process to show an example of a flow of a method of manufacturing the semiconductor package 10.

In the present embodiment, first, the base board 20 including the base board main body 21, the first insulation portion 22, and the first conductive portion 23 is prepared ((a) in FIG. 5). As a method of forming the first insulation portion 22 and the first conductive portion 23 on the surface of the base board main body 21, techniques known in the related art can be used.

Next, when the surface of the first conductive portion 23 is covered with the molecular bonding agent (i.e., when the molecular bonding agent is applied to the surface of the first conductive portion 23), the first molecular bonding layer 41 is formed ((b) in FIG. 5). The “molecular bonding layer” described in the manufacturing method in the present disclosure may refer to a molecular bonding layer, at least a part (e.g., whole part) of which has not yet chemically reacted (e.g., has not chemically bonded), in addition to a molecular bonding layer that has chemically reacted (e.g., chemically bonded). The molecular bonding layer, at least a part of which has not yet chemically reacted, may also be understood as a “layer of the molecular bonding agent.”

The first molecular bonding layer 41 is formed, for example, by a molecular bonding agent solution including the above-described molecular bonding agent being applied to a surface of the base board 20. As an exemplary method of applying the molecular bonding agent solution, a method of immersing the base board 20 in the molecular bonding agent solution and a method of spraying the molecular bonding agent solution on the base board 20 can be employed.

When the surface of the base board 20 is covered with the molecular bonding agent, the molecular bonding agent solution is preferably used. The molecular bonding agent solution can be prepared by dissolving the above-described molecular bonding agent in a solvent.

Exemplary solvents include water; alcohols such as methanol, ethanol, isopropanol, ethylene glycol, propylene glycol, cellosolve and carbitol; ketones such as acetone, methyl ethyl ketone and cyclohexanone; aromatic hydrocarbons such as benzene, toluene and xylene; aliphatic hydrocarbons such as hexane, octane, decane, dodecane and octadecane; esters such as ethyl acetate, methyl propionate and methyl phthalate; and ethers such as tetrahydrofuran, ethyl butyl ether and anisole. In addition, a mixed solvent in which such solvents are mixed can be used.

A concentration of the molecular bonding agent solution is preferably 0.001 mass % or more and 1 mass % or less and more preferably 0.01 mass % or more and 0.1 mass % or less with respect to a total mass of the molecular bonding agent solution. When the concentration of the molecular bonding agent solution is the above limit value or more, it is possible to increase a coverage ratio of the molecular bonding agent and further increase adhesiveness between members. When the concentration of the molecular bonding agent solution is the upper limit value or less, since it is difficult to include a molecular bonding agent that does not chemically bond (e.g., covalently bond), it is possible to ensure an electrical connection between the first conductive portion 23 or the second conductive portion 33 and the third conductive portion 52. In addition, it is possible to suppress a thickness of the semiconductor package 10 from increasing due to the first molecular bonding layer 41.

The prepared molecular bonding agent solution is applied to the surface of the first conductive portion 23 in the base board 20. When the base board 20 to which the molecular bonding agent solution has been applied is left, chemical bonding (e.g., covalent bonding) between the first conductive material 23m of the first conductive portion 23 and the molecular bonding agent is promoted. Further, an operation of applying energy (e.g., heat or light (e.g., ultraviolet rays)) to the first molecular bonding layer 41 may be performed. According to the operation of applying energy, chemical bonding (e.g., covalent bonding) between the molecular bonding agent and the first conductive material 23m is further promoted. As the energy, for example, heat can be used. When heat is used, heating at about 150° C. to 200° C. is performed for 5 minutes or more, preferably 60 minutes or more, more preferably 80 minutes or more, still more preferably 120 minutes or more, and most preferably 240 minutes or less. For example, depending on a material of the molecular bonding layer, a time period between 5 minutes and 120 minutes, preferably 60 minutes and 240 minutes, and more preferably 80 minutes and 240 minutes may be selected. Then, the base board 20 may be cleaned and then dried to remove an excess molecular bonding agent or solution. A cleaning solution can be selected from, for example, the same solvents described above used in the molecular bonding agent solution. A drying operation can be performed at 150° C. to 200° C. According to such an operation, the base board 20 in which the surface of the first conductive portion 23 is covered with the molecular bonding agent (e.g., the molecular bonding system 40r) is obtained.

The first conductive material 23m of the first conductive portion 23 covered with the molecular bonding agent forms a chemical bond (i.e., a covalent bond) with the molecular bonding agent (e.g., the molecular bonding system 40r). That is, the first molecular bonding layer 41 including the molecular bonding agent (e.g., the molecular bonding system 40r) that is chemically bonded (i.e., covalently bonded) to the first conductive material 23m included in the first conductive portion 23 is formed on the surface of the first conductive portion 23.

The molecular bonding agent solution may be applied to not only the surface of the first conductive portion 23 but also the surface of the first insulation portion 22. When both the surface of the first conductive portion 23 and the surface of the first insulation portion 22 are covered with the molecular bonding agent, the molecular bonding layer 40 including the molecular bonding agent (e.g., the molecular bonding system 40r) that is chemically bonded (i.e., covalently bonded) to the first conductive material 23m included in the first conductive portion 23 and the first insulating material 22m included in the first insulation portion 22 can be formed on both the surface of the first conductive portion 23 and the surface of the first insulation portion 22.

The thickness of the first molecular bonding layer 41 can be adjusted according to conditions such as a concentration and an applied amount of the molecular bonding agent solution, a cleaning time, and the number of cleanings.

Similarly, the semiconductor chip 30 including the semiconductor chip main body 31, the second insulation portion 32, and the second conductive portion 33 is prepared ((c) in FIG. 5). Then, by covering the surface of the second conductive portion 33 and the surface of the second insulation portion 32 with the molecular bonding agent (i.e., applying the molecular bonding agent to the surface of the second conductive portion 33 and the surface of the second insulation portion 32), the second molecular bonding layer 42 is formed ((d) in FIG. 5). In the present embodiment, similarly to the operation performed on the base board 20, the above-described molecular bonding agent solution is applied to the surface of the semiconductor chip 30 to form the second molecular bonding layer 42. The same operation of leaving, operation of applying energy, and operation of cleaning and drying as those in the above may be performed. In the present embodiment, through this process, the molecular bonding agent is chemically bonded (e.g., covalently bonded) to the second conductive material 33m and the second insulating material 32m. As a result, the surfaces of the second conductive portion 33 and the second insulation portion 32 are covered with the molecular bonding agent, and the second molecular bonding layer 42 including the molecular bonding agent (e.g., the molecular bonding system 40r) that is chemically bonded (e.g., covalently bonded) to the second conductive material 33m included in the second conductive portion 33 and the second insulating material 32m included in the second insulation portion 32 is formed on both the surface of the second conductive portion 33 and the surface of the second insulation portion 32.

Next, paste P including the resin 52b and the conductive particles 52a to serve as the third conductive portion 52 is applied on the first conductive portion 23 on the base board 20 ((e) in FIG. 5). As a result, at least a part of the first molecular bonding layer 41 (i.e., a molecular bonding agent that forms the first molecular bonding layer 41) is brought into contact with the resin 52b and the conductive particles 52a of the third conductive portion 52. Further, the resin 52b and the conductive particles 52a of the third conductive portion 52 and the first molecular bonding layer 41 may be chemically bonded (e.g., covalently bonded). Further, in the present embodiment, the third insulating material 51m serving as a constituent material of the third insulation portion 51 is formed on the first insulation portion 22 on the base board 20. As a result, at least a part of the first molecular bonding layer 41 (i.e., a molecular bonding agent that forms the first molecular bonding layer 41) is brought into contact with the third insulating material 51m of the third insulation portion 51. Further, the third insulating material 51m of the third insulation portion 51 and the first molecular bonding layer 41 may be chemically bonded (e.g., covalently bonded).

Further, in the present embodiment, after the third insulating material 51m and the paste P are formed on the base board 20, the base board 20 is formed on a heated metal stage. The subsequent operation is performed on the metal stage for preheating before curing of the resin 52b to be described below and an operation of applying energy to the molecular bonding layer 40 are performed. Specifically, the metal stage having a temperature of 150° C. to 170° C. is prepared and the base board 20 is placed on the metal stage for 10 seconds to 240 seconds.

Next, the semiconductor chip 30 is formed on the paste P and the third insulating material 51m. That is, the semiconductor chip 30 is placed such that the second conductive portion 33 is positioned on the paste P and the second insulation portion 32 is positioned on the third insulation portion 51 ((f) in FIG. 5). That is, when the third conductive portion 52 is interposed between the first conductive portion 23 and the second conductive portion 33, at least a part of the second molecular bonding layer 42 (i.e., a molecular bonding agent that forms the second molecular bonding layer 42) is brought into contact with the resin 52b and the conductive particles 52a of the third conductive portion 52. As a result, the resin 52b and the conductive particles 52a of the third conductive portion 52 and the second molecular bonding layer 42 may be chemically bonded (e.g., covalently bonded). In addition, when the third insulation portion 51 is interposed between the first insulation portion 22 and the second insulation portion 32, at least a part of the second molecular bonding layer 42 (i.e., a molecular bonding agent that forms the second molecular bonding layer 42) is brought into contact with the third insulating material 51m of the third insulation portion 51. As a result, the third insulating material 51m of the third insulation portion 51 and the second molecular bonding layer 42 may be chemically bonded (e.g., covalently bonded).

In the present embodiment, an operation of pressing the semiconductor chip 30 against the base board 20 while the semiconductor package 10 is heated at a higher temperature and setting the semiconductor package 10 to have an arbitrary thickness may be performed. For example, the pressing may be performed such that the semiconductor package 10 is pressed from above the semiconductor chip 30 using a pressing member. As conditions to heat at a higher temperature, the metal stage and the pressing member may be heated to a temperature of 180° C. to 200° C. According to this operation, the third insulating material 51m is cured at a portion between the first insulation portion 22 and the second insulation portion 32, and the third insulation portion 51 is formed. The resin 52b is cured at a portion between the first conductive portion 23 and the second conductive portion 33, and the third conductive portion 52 is formed. The intermediate layer 50 is formed by the third insulation portion 51 and the third conductive portion 52.

According to this operation, further, heat energy is applied to the first molecular bonding layer 41 and the second molecular bonding layer 42 and chemical bonding (e.g., covalent bonding) between each of the resin 52b and the conductive particles 52a and the molecular bonding agent is promoted. For example, chemical bonding (e.g., covalent bonding) between the resin 52b and the conductive particles 52a included in the third conductive portion 52 and the molecular bonding agent included in the first molecular bonding layer 41 is promoted. Chemical bonding (e.g., covalent bonding) between the third insulating material 51m included in the third insulation portion 51 and the molecular bonding agent included in the first molecular bonding layer 41 is promoted. In addition, chemical bonding (e.g., covalent bonding) between the resin 52b and the conductive particles 52a included in the third conductive portion 52 and the molecular bonding agent included in the second molecular bonding layer 42 is promoted. Chemical bonding (e.g., covalent bonding) between the third insulating material 51m included in the third insulation portion 51 and the molecular bonding agent included in the second molecular bonding layer 42 is promoted. As a result, the molecular bonding agent is chemically bonded (e.g., covalently bonded) to the first and second conductive materials 23m and 33m, the resin 52b, and the conductive particles 52a and is chemically bonded (e.g., covalently bonded) to the first insulating material 22m, the second insulating material 32m and the third insulating material 51m.

In the present embodiment, chemical bonding (e.g., covalent bonding) of the molecular bonding agent may be performed without applying heat or light energy. Alternatively, chemical bonding (e.g., covalent bonding) of the molecular bonding agent may be performed by applying heat or light energy.

### Second Embodiment

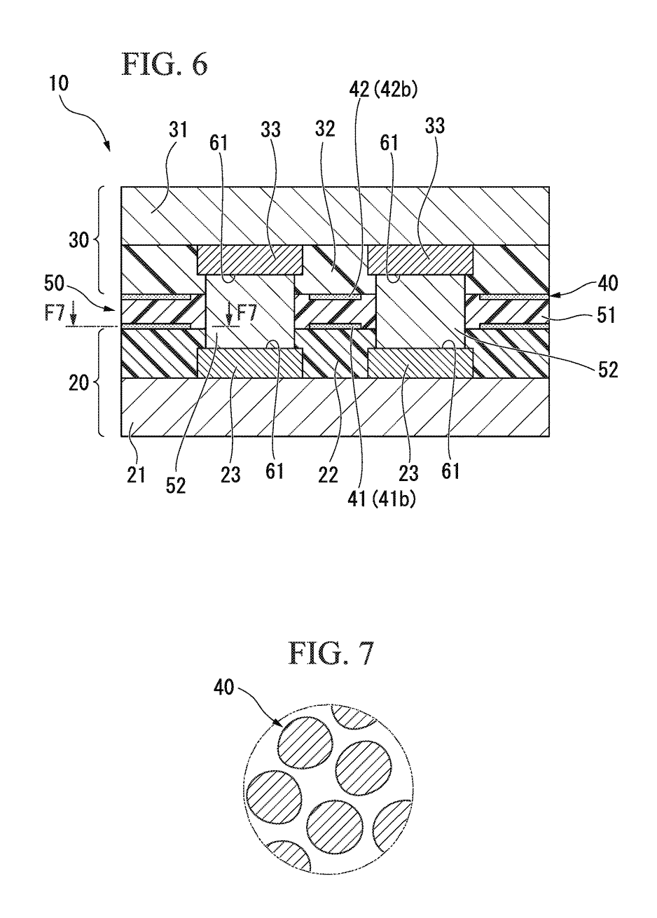

A second embodiment will be described with reference to FIG. 6 to FIG. 9. The second embodiment is different from the first embodiment in that the molecular bonding layer 40 is not formed in regions corresponding to the first conductive portion 23 and the second conductive portion 33. Configurations not described below are the same as those in the first embodiment.

FIG. 6 is a cross-sectional view of the semiconductor package 10 according to the second embodiment.

As shown in FIG. 6, the first molecular bonding layer 41 of the second embodiment forms a bonding layer absent portion (i.e., a bonding layer absent region) 61 in which the first molecular bonding layer 41 is not present in at least a part of a boundary between the first conductive portion 23 and the third conductive portion 52. The bonding layer absent portion 61 is an example of a “space”. The bonding layer absent portion 61 is defined by a first region of the first conductive portion 23 and a second region of the third conductive portion 52, the second region facing the first region. The bonding layer absent portion 61 extends at least two dimensionally. For example, the first molecular bonding layer 41 forms the bonding layer absent portion 61 in the entire boundary between the first conductive portion 23 and the third conductive portion 52. The conductive particles 52a of the third conductive portion 52 are formed in the bonding layer absent portion 61 of the first molecular bonding layer 41 and are in contact with the surface of the first conductive portion 23. As a result, the third conductive portion 52 and the first conductive portion 23 are electrically connected more reliably.

Similarly, the second molecular bonding layer 42 of the present embodiment forms the bonding layer absent portion 61 in which the second molecular bonding layer 42 is not present in at least a part of a boundary between the second conductive portion 33 and the third conductive portion 52. The bonding layer absent portion 61 is an example of a “space”. The bonding layer absent portion 61 is defined by a first region of the second conductive portion 33 and a second region of the third conductive portion 52, the second region facing the first region. The bonding layer absent portion 61 extends at least two dimensionally. For example, the second molecular bonding layer 42 forms the bonding layer absent portion 61 in the entire boundary between the second conductive portion 33 and the third conductive portion 52. The conductive particles 52a of the third conductive portion 52 are formed in the bonding layer absent portion 61 of the second molecular bonding layer 42 and are in contact with the surface of the second conductive portion 33. As a result, the third conductive portion 52 and the second conductive portion 33 are electrically connected more reliably.

FIG. 7 is a cross-sectional view of the molecular bonding layer 40 along a line F7-F7 in FIG. 6.

As shown in FIG. 7, the molecular bonding systems 40r of the molecular bonding layer 40 of the present embodiment are relatively uniformly dispersed. According to this molecular bonding layer 40, compared to the first embodiment, it is possible to increase bonding strengths between the first insulation portion 22 and the third insulation portion 51 and between the second insulation portion 32 and the third insulation portion 51. On the other hand, when the molecular bonding systems 40r are relatively uniformly dispersed between the first conductive portion 23 and the third conductive portion 52 and between the second conductive portion 33 and the third conductive portion 52, the conductive particles 52a of the third conductive portion 52 are obstructed by the molecular bonding systems 40r and is less likely to contact the first conductive portion 23 or the second conductive portion 33. For that reason, there is a possibility that electrical connection strengths between the first conductive portion 23 and the third conductive portion 52 and between the second conductive portion 33 and the third conductive portion 52 decrease.

According to the present embodiment, the molecular bonding layer 40 forms the bonding layer absent portion 61 in which the molecular bonding layer 40 is not formed in at least a part of at least one of the boundary between the first conductive portion 23 and the third conductive portion 52 and the boundary between the second conductive portion 33 and the third conductive portion 52. The conductive particles 52a of the third conductive portion 52 are formed in the bonding layer absent portion 61 and are in contact with the first conductive portion 23 or the second conductive portion 33. According this structure, electrical connection strengths between the first conductive portion 23 and the third conductive portion 52 and between the second conductive portion 33 and the third conductive portion 52 increase. Here, in the molecular bonding layer 40 of this embodiment, the molecular bonding systems 40r may be relatively uniformly dispersed as shown in FIG. 7 or the molecular bonding systems 40r may be non-uniformly dispersed as shown in FIG. 4.

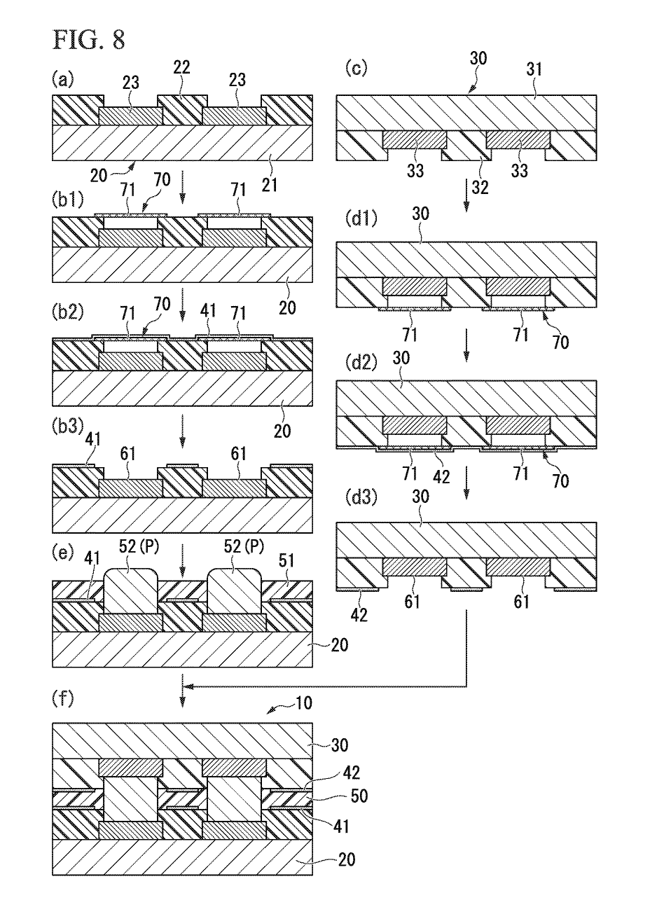

FIG. 8 is a cross-sectional view of a structure in process to show a flow of a method of manufacturing the semiconductor package 10 according to the present embodiment. Hereinafter, only points different from the first embodiment will be described.

In the present embodiment, before the molecular bonding agent is applied to the base board 20, a mask (e.g., a resist) 70 is disposed on the surface of the base board 20 ((b1) in FIG. 8). For example, the mask 70 is disposed to cover the first conductive portions 23. The mask 70 may be preferably made of, for example, a fluorine-based material to which the molecular bonding agent is less likely to stick. However, the material of the mask 70 is not particularly limited.

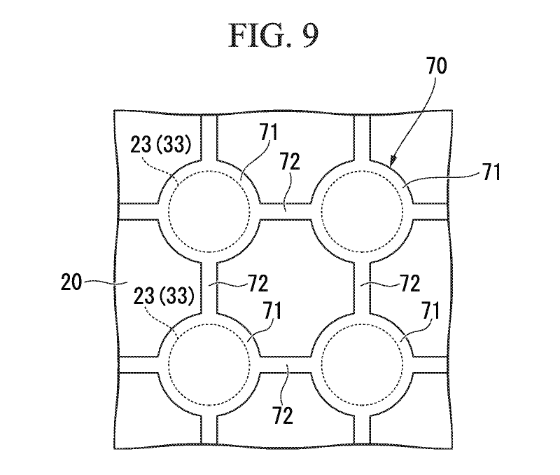

FIG. 9 is a plan view of the mask 70. As shown in FIG. 9, the mask 70 includes, for example, a plurality of covers 71 and a plurality of connecting portions 72. The plurality of covers 71 corresponds to the plurality of first conductive portions 23 and covers the plurality of first conductive portions 23. The plurality of connecting portions 72 extends between the plurality of covers 71 and connects the plurality of covers 71. For that reason, the mask 70 including the plurality of covers 71 can be integrally attached to and removed from the base board 20.

Next, in a s state where the plurality of first conductive portions 23 of the base board 20 is covered by the mask 70, the molecular bonding agent is applied to the surface of the first insulation portion 22 of the base board 20 (i.e., the surface of the first insulation portion 22 is coated with the molecular bonding agent) ((b2) in FIG. 8). Then, the mask 70 is removed from the base board 20 ((b3) in FIG. 8). As a result, the first molecular bonding layer 41 can be formed on the first insulation portion 22 and the bonding layer absent portion 61 can be formed on the first conductive portion 23.

Similarly, before the molecular bonding agent is applied to the semiconductor chip 30, the mask (e.g., the resist) 70 is disposed on the surface of the semiconductor chip 30 ((d1) in FIG. 8). For example, the mask 70 is disposed to cover the second conductive portion 33. For example, similarly to the mask 70 shown in FIG. 9, the mask 70 includes the plurality of covers 71 and the plurality of connecting portions 72. The plurality of covers 71 corresponds to the plurality of second conductive portion 33 and covers the plurality of second conductive portions 33.

Next, in a state where the plurality of second conductive portions 33 of the semiconductor chip 30 is covered by the mask 70, the molecular bonding agent is applied to the second insulation portion 32 of the surface of the semiconductor chip 30 (i.e., the surface of the second insulation portion 32 is coated with the molecular bonding agent) ((d2) in FIG. 8). Then, the mask 70 is removed from the semiconductor chip 30 ((d3) in FIG. 8). As a result, the second molecular bonding layer 42 can be formed on the second insulation portion 32 and the bonding layer absent portion 61 can be formed on the second conductive portion 33.

The subsequent processes are the same as those in the first embodiment.

### Third Embodiment

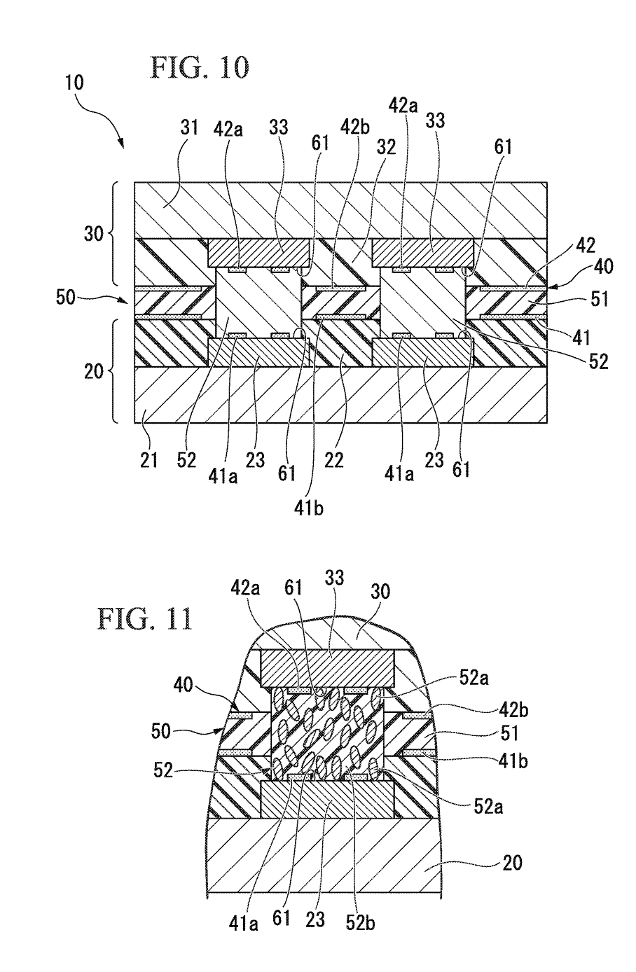

Next, a third embodiment will be described with reference to FIG. 10 to FIG. 12. The third embodiment is different from the second embodiment in that the bonding layer absent portions 61 are formed to correspond to a part of the first conductive portion 23 and a part of the second conductive portion 33. Configurations not described below are the same as those in the second embodiment.

FIG. 10 is a cross-sectional view of the semiconductor package 10 according to the third embodiment.

As shown in FIG. 10, in the present embodiment, the first molecular bonding layer 41 forms the bonding layer absent portion 61 in a part of the boundary between the first conductive portion 23 and the third conductive portion 52. In other words, a part of the first molecular bonding layer 41 is formed in a part of the boundary between the first conductive portion 23 and the third conductive portion 52 and joins the first conductive portion 23 and the third conductive portion 52. As a result, both an electrical connection strength and a physical connection strength between the first conductive portion 23 and the third conductive portion 52 increase.

FIG. 11 is an enlarged cross-sectional view of a vicinity of the first conductive portion 23.

As shown in FIG. 11, the conductive particles 52a included in the third conductive portion 52 are formed in the bonding layer absent portion 61 and are in contact with the first conductive portion 23. In other words, the conductive particles 52a included in the third conductive portion 52 are in contact with the first conductive portion 23 in a region in which the first molecular bonding layer 41 is not formed. As a result, electrical connection strength between the conductive particles 52a and the first conductive portion 23 is ensured more reliably.

Similarly, in the present embodiment, the second molecular bonding layer 42 forms the bonding layer absent portion 61 in a part of the boundary between the second conductive portion 33 and the third conductive portion 52. In other words, a part of the second molecular bonding layer 42 is formed in a part of the boundary between the second conductive portion 33 and the third conductive portion 52 and joins the second conductive portion 33 and the third conductive portion 52. As a result, both electrical connection strength and a physical connection strength between the second conductive portion 33 and the third conductive portion 52 increase.

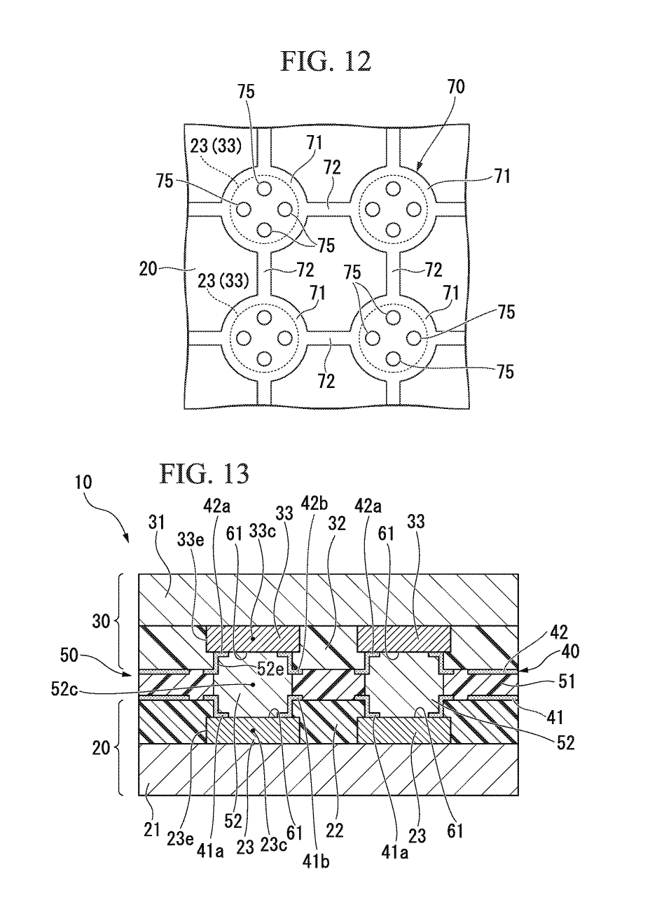

FIG. 12 is a plan view of the mask 70 according to the present embodiment.

As shown in FIG. 12, each of the covers 71 of the mask 70 of the present embodiment includes a plurality of openings 75. The plurality of openings 75 faces at least a part of the first conductive portion 23 (or the second conductive portion 33). In a portion corresponding to the opening 75 within the first conductive portion 23 and the second conductive portion 33, the molecular bonding layer 40 is formed by the molecular bonding agent being applied through the opening 75. On the other hand, in a portion in which the openings 75 are not formed, the molecular bonding agent is not applied, and the bonding layer absent portion 61 is formed.

An aperture ratio of the openings 75 with respect to the entire area of the cover 71 is set to be lower than a ratio (e.g., a volume ratio or a mass ratio) of the resin 52b with respect to the entire third conductive portion 52. For example, when 60% of the third conductive portion 52 is formed of the conductive particles 52a and 40% is formed of the resin 52b according to a volume or mass ratio, an aperture ratio of the openings 75 with respect to the cover 71 is set to a value (e.g., 20%) smaller than 40%. As a result, it is possible to bring the conductive particles 52a into contact with the first conductive portion 23 or the second conductive portion 33 more reliably.

### Fourth Embodiment

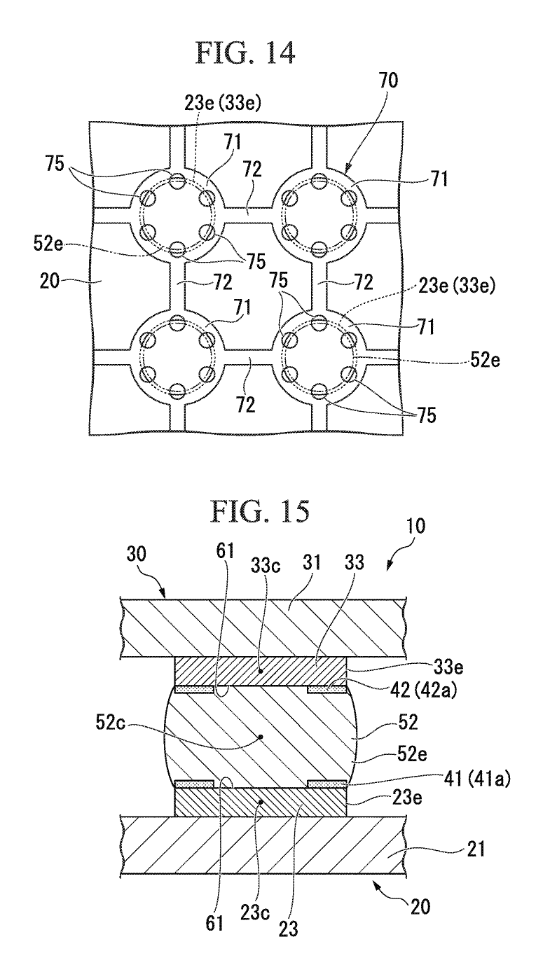

A fourth embodiment will be described with reference to FIG. 13 and FIG. 14. The fourth embodiment is different from the third embodiment in that the bonding layer absent portion 61 is separated from at least a part of an edge 52e of the third conductive portion 52. Configurations not described below are the same as those in the third embodiment.

FIG. 13 is a cross-sectional view of the semiconductor package 10 according to the fourth embodiment.

As shown in FIG. 13, in the present embodiment, the first molecular bonding layer 41 forms the bonding layer absent portion 61 at a position different from at least a part of an edge (e.g., a peripheral portion) 23e of the first conductive portion 23 and at least a part of an edge (e.g., a peripheral portion) 52e of the third conductive portion 52. That is, the first molecular bonding layer 41 forms the bonding layer absent portion 61 that is separated from at least a part of an edge (e.g., a peripheral portion) 23e of the first conductive portion 23 and at least a part of an edge (e.g., a peripheral portion) 52e of the third conductive portion 52. In other words, at least a part of the first molecular bonding layer 41 is formed on the edge (e.g., the peripheral portion) 23e of the first conductive portion 23 and the edge (e.g., the peripheral portion) 52e of the third conductive portion 52. As a result, in the edge (e.g., the peripheral portion) 23e of the first conductive portion 23 and the edge (e.g., the peripheral portion) 52e of the third conductive portion 52 which tend to receive a force when the semiconductor package 10 thermally expands, a joint strength between the first conductive portion 23 and the third conductive portion 52 is increased due to the first molecular bonding layer 41. As a result, it is possible to increase reliability and a lifespan of the semiconductor package 10. The “corresponding position” referred to herein means an overlapping position when the base board 20 is viewed in a plan view (i.e., when viewed in a thickness direction of the base board 20 and when the molecular bonding layers 41 and 42 are viewed in a plan view). For example, at least a part of the first molecular bonding layer 41 joints the edge (e.g., the peripheral portion) 52e of the third conductive portion 52 and the first conductive portion 23.

Similarly, in the present embodiment, the second molecular bonding layer 42 forms the bonding layer absent portion 61 at a position different from at least a part of an edge (e.g., a peripheral portion) 33e of the second conductive portion 33 and at least a part of an edge (e.g., a peripheral portion) 52e of the third conductive portion 52. That is, the second molecular bonding layer 42 forms the bonding layer absent portion 61 that is separated from at least a part of an edge (e.g., a peripheral portion) 33e of the second conductive portion 33 and at least a part of an edge (e.g., a peripheral portion) 52e of the third conductive portion 52. In other words, at least a part of the second molecular bonding layer 42 is formed on the edge (e.g., the peripheral portion) 33e of the second conductive portion 33 and the edge (e.g., the peripheral portion) 52e of the third conductive portion 52. As a result, in the edge (e.g., the peripheral portion) 33e of the second conductive portion 33 and the edge (e.g., the peripheral portion) 52e of the third conductive portion 52 which tend to receive a force when the semiconductor package 10 thermally expands, a joint strength between the second conductive portion 33 and the third conductive portion 52 is increased due to the second molecular bonding layer 42. As a result, it is possible to increase reliability and a lifespan of the semiconductor package 10. For example, at least a part of the second molecular bonding layer 42 joins the edge (e.g., the peripheral portion) 52e of the third conductive portion 52 and the second conductive portion 33.

FIG. 14 is a plan view of the mask 70 according to the present embodiment.

As shown in FIG. 14, the mask 70 according to the present embodiment includes the plurality of openings 75. In the present embodiment, the plurality of openings 75 is formed at regions corresponding to a part of the edge (e.g., the peripheral portion) 23e of the first conductive portion 23 and a part of the edge (e.g., the peripheral portion) 52e of the third conductive portion 52. For example, at least one of the openings 75 (e.g., the plurality of openings 75) is formed at a region overlapping a part of the edge 23e of the first conductive portion 23 and a part of the edge 52e of the third conductive portion 52. For that reason, the first molecular bonding layer 41 is formed at a position corresponding to the edge (e.g., the peripheral portion) 23e of the first conductive portion 23 and the edge (e.g., the peripheral portion) 52e of the third conductive portion 52.

In addition, in a different point of view, the plurality of openings 75 is formed at regions corresponding to a part of the edge (e.g., the peripheral portion) 33e of the second conductive portion 33 and a part of the edge (e.g., the peripheral portion) 52e of the third conductive portion 52. For example, at least one of the openings 75 (e.g., the plurality of openings 75) is formed at a region overlapping a part of the edge 33e of the second conductive portion 33 and a part of the edge 52e of the third conductive portion 52. For that reason, the second molecular bonding layer 42 is formed at a position corresponding to the edge (e.g., the peripheral portion) 33e of the second conductive portion 33 and the edge (e.g., the peripheral portion) 52e of the third conductive portion 52.

In the present embodiment, when the mask 70 is viewed in a plan view, more of the plurality of openings 75 are distributed in a region corresponding to the edge (e.g., the peripheral portion) 52e of the third conductive portion 52 than in a region corresponding to a central part 52c of the third conductive portion 52. For that reason, in the edge (e.g., the peripheral portion) 52e of the third conductive portion 52 which tends to receive a force when the semiconductor package 10 thermally expands, a joint strength of the third conductive portion 52 increases. As a result, it is possible to further increase reliability and a lifespan of the semiconductor package 10. In another view point, the mask 70 has a distribution of density of the openings 75. The mask 70 has a portion having a first distance defined from a periphery edge of the cover 71. The portion is greater in the distribution of density than the remaining portions of the mask 70.

In addition, in a different point of view, when the mask 70 is viewed in a plan view, more of the plurality of openings 75 are distributed in a region corresponding to the edge (e.g., the peripheral portion) 23e of the first conductive portion 23 or the edge (e.g., the peripheral portion) 33e of the second conductive portion 33 than in a region corresponding to a central part 23c of the first conductive portion 23 or a central part 33c of the second conductive portion 33. For that reason, in the edge (e.g., the peripheral portion) 23e of the first conductive portion 23 or the edge (e.g., the peripheral portion) 33e of the second conductive portion 33 which tends to receive a force when the semiconductor package 10 thermally expands, a joint strength of the first conductive portion 23 or the second conductive portion 33 increases. As a result, it is possible to further increase reliability and a lifespan of the semiconductor package 10.

FIG. 15 is a cross-sectional view of a part of the semiconductor package 10 according to a modified example of the present embodiment. As shown in FIG. 15, the bonding layer absent portion 61 may be formed at a position corresponding to the central part 23c of the first conductive portion 23, and the first molecular bonding layer 41 may be formed at a position corresponding to the edge (e.g., the peripheral part) 23e of the first conductive portion 23. Similarly, the bonding layer absent portion 61 may be formed at a position corresponding to the central part 33c of the second conductive portion 33, and the second molecular bonding layer 42 may be formed at a position corresponding to the edge (e.g., the peripheral part) 33e of the second conductive portion 33. For that reason, in the edge (e.g., the peripheral part) 23e of the first conductive portion 23 and the edge (e.g., the peripheral part) 33e of the second conductive portion 33 which tend to receive a force when the semiconductor package 10 thermally expands, a joint strength between the first conductive portion 23 and the second conductive portion 33 increases. As a result, it is possible to further increase reliability and a lifespan of the semiconductor package 10. Also, in at least this modified example, the third conductive portion 52 may be a solder connection portion (e.g., a solder bump and a solder ball) or the like.

### Fifth Embodiment

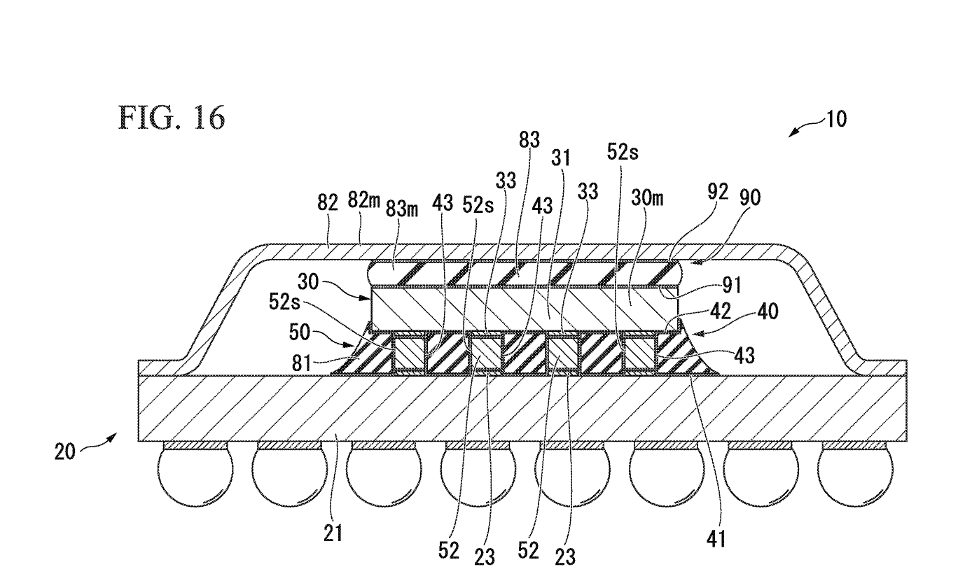

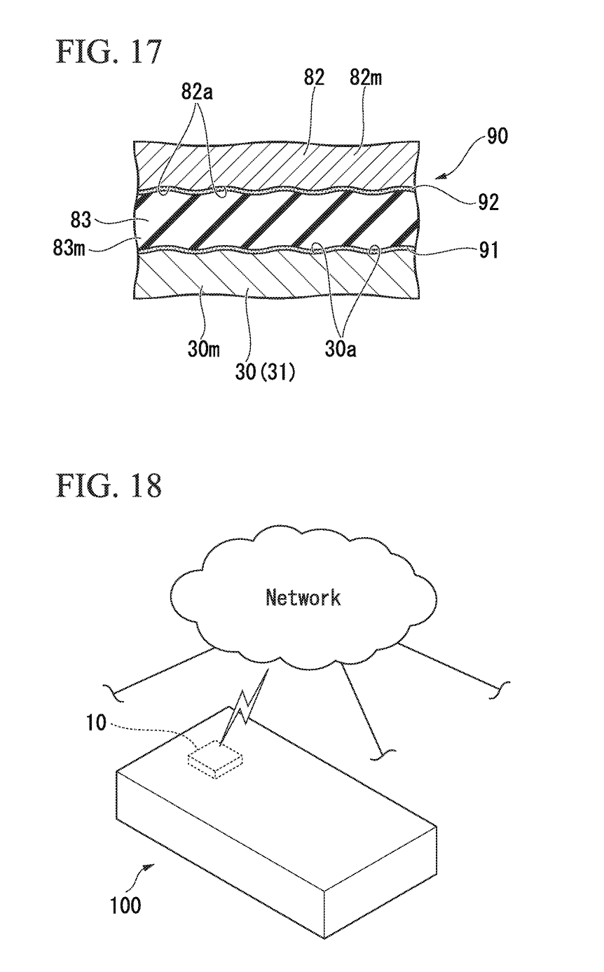

Next, a fifth embodiment will be described with reference to FIG. 16 and FIG. 17. The fifth embodiment is different from the first embodiment in that a molecular bonding layer 90 is further formed between the semiconductor chip 30 and a heat dissipation member 82. Configurations not described below are the same as those in the first embodiment.

FIG. 16 is a cross-sectional view of the semiconductor package 10 according to the fifth embodiment.

As shown in FIG. 16, the semiconductor package 10 includes, for example, the base board 20, the semiconductor chip 30, the plurality of third conductive portions 52, an underfill 81, the molecular bonding layer 40, the heat dissipation member 82, a heat conductive sheet 83, and the molecular bonding layer 90.

The base board 20 of the present embodiment includes the base board main body 21 and the first conductive portion 23 formed on the surface of the base board main body 21. For example, the first conductive portion 23 is a conductive pad (i.e., a connection portion, an electrical connection portion, and a terminal portion).

The semiconductor chip 30 of the present embodiment includes the semiconductor chip main body 31 and the second conductive portion 33 formed on the surface of the semiconductor chip main body 31. For example, the second conductive portion 33 is a conductive pad (i.e., a connection portion, an electrical connection portion, and a terminal portion).

The third conductive portion 52 is formed between the first conductive portion 23 of the base board 20 and the second conductive portion 33 of the semiconductor chip 30, and electrically connects the first conductive portion 23 and the second conductive portion 33. For example, the third conductive portion 52 is a solder connection portion (e.g., a solder bump and a solder ball).

The underfill 81 (i.e., the insulation portion) is formed between the base board 20 and the semiconductor chip 30. At least a part of the underfill 81 is formed between the plurality of third conductive portions 52 and electrically insulates the plurality of third conductive portions 52. The underfill 81 is made of a thermosetting or thermoplastic insulating resin.

The molecular bonding layer 40 of the present embodiment includes the first molecular bonding layer 41, the second molecular bonding layer 42, and a third molecular bonding layer 43. The first molecular bonding layer 41 is formed between the first conductive portion 23 and the third conductive portion 52 and between the surface of the base board main body 21 and the underfill 81. The second molecular bonding layer 42 is formed between the second conductive portion 33 and the third conductive portion 52 and between the surface of the semiconductor chip main body 31 and the underfill 81. The third molecular bonding layer 43 is formed between a circumference 52s of the third conductive portion 52 and the underfill 81 and joins the circumference 52s of the third conductive portion 52 and the underfill 81. Similarly to the first molecular bonding layer 41 or the second molecular bonding layer 42, the third molecular bonding layer 43 is formed by the molecular bonding agent (e.g., triazine derivatives) described above. Here, the underfill 81 is likely to expand due to heat generation of the semiconductor chip 30. According to the present embodiment, a strength between the underfill 81 and the base board 20, between the underfill 81 and the semiconductor chip 30, and between the underfill 81 and the third conductive portions 52 is increased using the molecular bonding layer 40.

The heat dissipation member 82 (e.g., a heatsink, a heat spreader) is, for example, a heat dissipation plate. The heat dissipation member 82 is positioned at a side opposite to the base board 20 with respect to the semiconductor chip 30 and is thermally connected to the semiconductor chip 30 via the heat conductive sheet 83 to be described below in detail. The heat dissipation member 82 dissipates at least a part of heat generated from the semiconductor chip 30 to the outside of the semiconductor package 10. The heat dissipation member 82 is made of, for example, metal, and has rigidity.

The heat conductive sheet 83 (i.e., a thermal connection sheet) is a thermal connection member having flexibility and is made of a resin material having favorable thermal conductivity. The heat conductive sheet 83 is disposed between the semiconductor chip 30 and the heat dissipation member 82. The heat conductive sheet 83 can be deformed to follow an unevenness or a slope of the surface of the semiconductor chip 30 and an unevenness or a slope of the surface of the heat dissipation member 82. The heat conductive sheet 83 thermally connects the heat dissipation member 82 to the semiconductor chip 30.

The molecular bonding layer 90 includes a first molecular bonding layer 91 and a second molecular bonding layer 92. Similarly to the first molecular bonding layer 41 and the second molecular bonding layer 42, the first molecular bonding layer 91 and the second molecular bonding layer 92 are formed by the molecular bonding agent (e.g., triazine derivatives) described above.

The first molecular bonding layer 91 is formed between the semiconductor chip 30 and the heat conductive sheet 83. The first molecular bonding layer 91 joins the semiconductor chip 30 and the heat conductive sheet 83. At least a part of the first molecular bonding layer 91 (i.e., at least a part of a molecular bonding agent that forms the first molecular bonding layer 91) is chemically bonded (e.g., covalently bonded) to a material 30m included in the semiconductor chip 30. Similarly, at least a part of the first molecular bonding layer 91 (i.e., at least a part of a molecular bonding agent that forms the first molecular bonding layer 91) is chemically bonded (e.g., covalently bonded) to a material 83m included in the heat conductive sheet 83. For example, at least one molecular bonding system 40r included in the first molecular bonding layer 91 is chemically bonded (e.g., covalently bonded) to both the material 30m of the semiconductor chip 30 and the material 83m of the heat conductive sheet 83. As a result, adhesiveness between the semiconductor chip 30 and the heat conductive sheet 83 increases and thermal connectivity between the semiconductor chip 30 and the heat conductive sheet 83 is improved. The material 83m is, for example, a resin material.

On the other hand, the second molecular bonding layer 92 is formed between the heat dissipation member 82 and the heat conductive sheet 83. The second molecular bonding layer 92 joins the heat dissipation member 82 and the heat conductive sheet 83. At least a part of the second molecular bonding layer 92 (i.e., at least a part of a molecular bonding agent that forms the second molecular bonding layer 92) is chemically bonded (e.g., covalently bonded) to a material 82m included in the heat dissipation member 82. Similarly, at least a part of the second molecular bonding layer 92 (i.e., at least a part of a molecular bonding agent that forms the second molecular bonding layer 92) is chemically bonded (e.g., covalently bonded) to the material 83m included in the heat conductive sheet 83. For example, at least one molecular bonding system 40r included in the second molecular bonding layer 92 is chemically bonded (e.g., covalently bonded) to both the material 82m of the heat dissipation member 82 and the material 83m of the heat conductive sheet 83. As a result, adhesiveness between the heat dissipation member 82 and the heat conductive sheet 83 increases and thermal connectivity between the heat dissipation member 82 and the heat conductive sheet is improved.

FIG. 17 is an enlarged cross-sectional view of a portion around the heat conductive sheet 83 of the present embodiment. As shown in FIG. 17, the surface of the semiconductor chip 30 includes fine depressions 30a as surface roughness. At least a part of the first molecular bonding layer 91 is formed inside the depression 30a. In the present embodiment, when the heat conductive sheet 83 is deformed according to the shape of the depression 30a, the semiconductor chip 30 and the heat conductive sheet 83 are joined by the first molecular bonding layer 91 also inside the depression 30a.

Similarly, the surface of the heat dissipation member 82 includes fine depressions 82a as surface roughness. At least a part of the second molecular bonding layer 92 is formed inside the depression 82a. In the present embodiment, when the heat conductive sheet 83 is deformed according to the shape of the depression 82a, the heat dissipation member 82 and the heat conductive sheet 83 are joined by the second molecular bonding layer 92 also inside the depression 82a.

FIG. 18 is a perspective view of an electronic device 100 of an embodiment. In the electronic device 100, the semiconductor package 10 according to one of the first to fifth embodiments and modified examples thereof is mounted. The electronic device 100 is an electronic device supporting, for example, Internet of Things (IoT), and can be connected to the Internet through wired or wireless communication. Also, the electronic device 100 is not limited to the above example. The electronic device 100 may be an electronic device for a vehicle or various electronic devices for other purposes.

According to at least one of the embodiments described above, it is possible to provide a semiconductor package with increased conductivity between a board and a semiconductor chip through an intermediate layer by increasing adhesion strength between at least one of the board and the semiconductor chip and a resin of the intermediate layer by the molecular bonding layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate including, on a surface thereof, a first conductive pad and a first insulating layer around the first conductive pad;
a semiconductor chip including, on a surface thereof, a second conductive pad and a second insulating layer around the second conductive pad;
an intermediate layer between the substrate and the semiconductor chip, and including a conductive portion between the first and second conductive pads, and an insulating portion between the first and second insulating layers; and
a molecular bonding layer between the substrate and the intermediate layer, and including at least one of a first molecular portion covalently bonded to a material of the first conductive pad and a material of the conductive portion of the intermediate layer, and a second molecular portion covalently bonded to a material of the first insulating layer and a material of the insulating portion of the intermediate layer.

2. The semiconductor device according to claim 1, wherein the molecular bonding layer includes the first molecular portion.

3. The semiconductor device according to claim 2, wherein
the conductive portion of the intermediate layer includes a conductive particle that is covalently bonded to the first molecular portion.

4. The semiconductor device according to claim 2, wherein
a coverage ratio of the molecular bonding layer on an exposed surface of the first conductive pad is greater than 20% and equal to or smaller than 80%.

5. The semiconductor device according to claim 1, wherein the molecular bonding layer includes the second molecular portion and does not include the first molecular portion.

6. The semiconductor device according to claim 1, wherein the molecular bonding layer includes both the first and second molecular portions.

7. The semiconductor device according to claim 1, wherein
at least a portion of the molecular bonding layer is a monomolecular layer.

8. The semiconductor device according to claim 1, wherein
at least part of the first conductive pad is in direct contact with the conductive portion of the intermediate layer.

9. The semiconductor device according to claim 1, wherein
at least part of the first insulating layer is in direct contact with the insulating portion of the intermediate layer.

10. The semiconductor device according to claim 1, further comprising:
a second molecular bonding layer formed between the semiconductor chip and the intermediate layer, and including at least one of a third molecular portion covalently bonded with a material of the second conductive pad and the material of the conductive portion of the intermediate layer, and a fourth molecular portion covalently bonded with a material of the second insulating layer and a material of the insulating portion of the intermediate layer.

11. The semiconductor device according to claim 1, wherein the molecular bonding layer includes a triazine dithiol residue.

12. A semiconductor device comprising:
a substrate including, on a surface thereof, a first conductive pad and a first insulating layer around the first conductive pad;
a semiconductor chip including, on a surface thereof, a second conductive pad and a second insulating layer around the second conductive pad;
an intermediate layer formed between the substrate and the semiconductor chip, and including a conductive portion between the first and second conductive pads, and an insulating portion between the first and second insulating layers; and
a molecular bonding layer formed between the semiconductor chip and the intermediate layer, and including at least one of a first molecular portion covalently bonded to a material of the second conductive pad and a material of the conductive portion of the intermediate layer, and a second molecular portion covalently bonded to a material of the second insulating layer and a material of the insulating portion of the intermediate layer.

13. The semiconductor device according to claim 12, wherein the molecular bonding layer includes the first molecular portion.

14. The semiconductor device according to claim 13, wherein
the conductive portion of the intermediate layer includes a conductive particle that is covalently bonded with the first molecular portion.

15. The semiconductor device according to claim 13, wherein
a coverage ratio of the molecular bonding layer on an exposed surface of the first conductive pad is greater than 20% and equal to or smaller than 80%.

16. The semiconductor device according to claim 13, wherein the molecular bonding layer includes the second molecular portion and does not include the first molecular portion.

17. The semiconductor device according to claim 13, wherein the molecular bonding layer includes both the first and second molecular portions.

18. The semiconductor device according to claim 13, wherein
at least a portion of the molecular bonding layer is a monomolecular layer.

19. The semiconductor device according to claim 13, wherein
at least part of the second conductive pad is in direct contact with the conductive portion of the intermediate layer.

20. The semiconductor device according to claim 13, wherein
at least part of the second insulating layer is in direct contact with the insulating portion of the intermediate layer.
